(19) United States
(12) Patent Application Publication
(10) Pub. No.: US 2012/0229969 A1
(43) Pub. Date: Sep. 13, 2012

(54) SLIM KEYBOARD WITH A FUNCTION OF A TABLET PERSONAL COMPUTER BRACKET

(76) Inventor: Shao-Chieh TING, Banchiau City (TW)

(21) Appl. No.: 13/044,305

(22) Filed: Mar. 9, 2011

(51) Int. Cl. H05K 7/00

(52) U.S. Cl. 361/679.09

(57) ABSTRACT

The present invention is assembled by a keyboard unit, a rotational keyboard cover and a rotational bracket. A rear part of the keyboard unit is provided with a bump which serves as a bracket to limit the position of a tablet personal computer, preventing the tablet personal computer from sliding downward. When the rotational keyboard cover is covered, dust can be prevented from entering into the keyboard; whereas, when the rotational bracket is pulled open at a same time when the keyboard cover is lifted open, the keyboard can be used as a bracket to emplace the tablet personal computer.

### BACKGROUND OF THE INVENTION

a) Field of the Invention

The present invention relates to a slim keyboard with a function of a tablet personal computer bracket, and more particularly to a keyboard which is able to prevent dust from entering and can also act as a bracket to emplace a tablet personal computer, through using collaboratively a keyboard unit, a rotational keyboard cover and a rotational bracket.

b) Description of the Prior Art

As development of technologies, a keyboard is getting thinner and thinner. There are a lot of slim keyboards on existing markets but their functions are simpler that they can be only used as the keyboards.

Through a keyboard cover and a rotational bracket, the present invention can be also used as a tablet personal computer bracket, in addition to being provided with the original functions of dust-proofing and protecting from collision.

### SUMMARY OF THE INVENTION

The primary object of the present invention is to provide a slim keyboard with a function of a tablet personal computer bracket, which includes primarily a slim keyboard unit, a keyboard cover and a rotational bracket.

Another object of the present invention is to provide the slim keyboard with the function of a tablet personal computer bracket, wherein the keyboard unit is provided with a bump to limit the position of a tablet personal computer.

Still another object of the present invention is to provide the slim keyboard with the function of a tablet personal computer bracket, wherein the rotational bracket is provided on the rotational keyboard cover and the rotational keyboard cover is covered on the keyboard unit.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a three-dimensional schematic view of the present invention.

FIG. 2 shows a three-dimensional exploded view of the present invention.

FIG. 3 shows a three-dimensional front view of the present invention, wherein the rotational keyboard cover and the bracket are turned open.

FIG. 4 shows a three-dimensional rear view of the present invention, wherein the rotational keyboard cover and the bracket are turned open.

FIG. 5 shows a three-dimensional front view of the present invention, with that a tablet personal computer is emplaced.

FIG. 6 shows a three-dimensional rear view of the present invention, with that the tablet personal computer is emplaced.

### DETAILED DESCRIPTION OF THE PREFERRED EMBODIMENTS

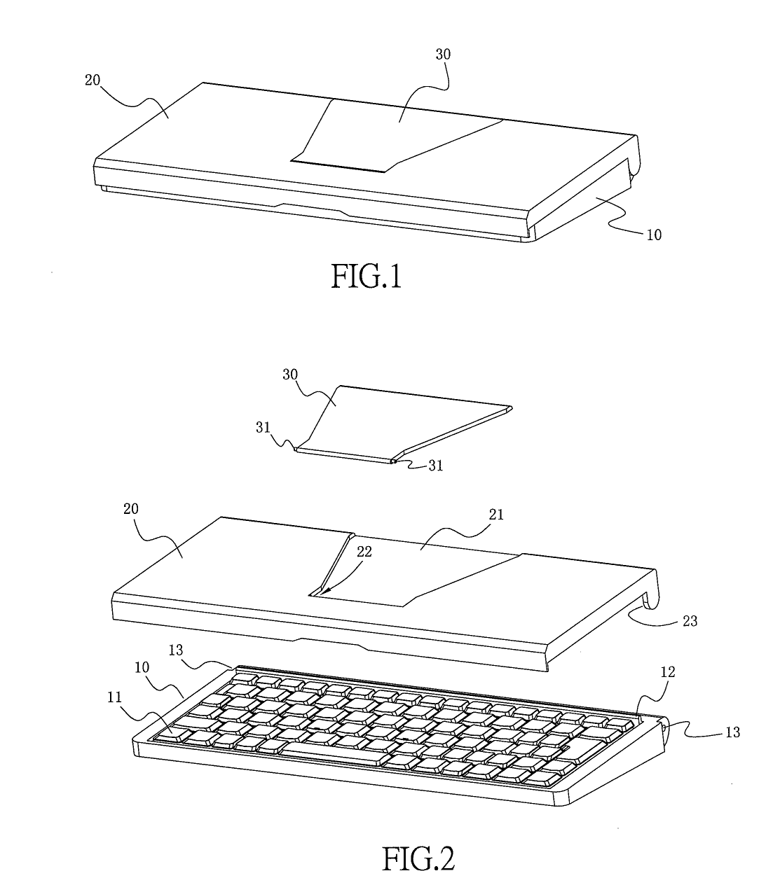

Referring to FIG. 1 and FIG. 2, it shows a three-dimensional schematic view and a three-dimensional exploded view of the present invention. As shown in the drawings, the present invention is a slim keyboard with a function of a tablet personal computer bracket, comprising a keyboard unit 10, a rotational keyboard cover 20 and a rotational bracket 30.

The keyboard unit 10 is provided with plural function keys 11, a bump 12 for limiting the position of a tablet personal computer and a shaft hole 13 at a rear part of two sides to sheathe with the rotational keyboard cover 20.

The rotational keyboard cover 20 is used to cover the keyboard unit 10 and is provided with a slot 21 to contain the rotational bracket 30. Two sides of the slot 21 are provided respectively with a shaft hole 22 for sheathing with the rotational bracket 30 and inner rear ends of two sides are provided respectively with a pivot 23.

The rotational bracket 30 is provided on the rotational keyboard cover 20 to support the rotational keyboard cover 20 and two sides of the rotational bracket 30 are provided respectively with a pivot 31.

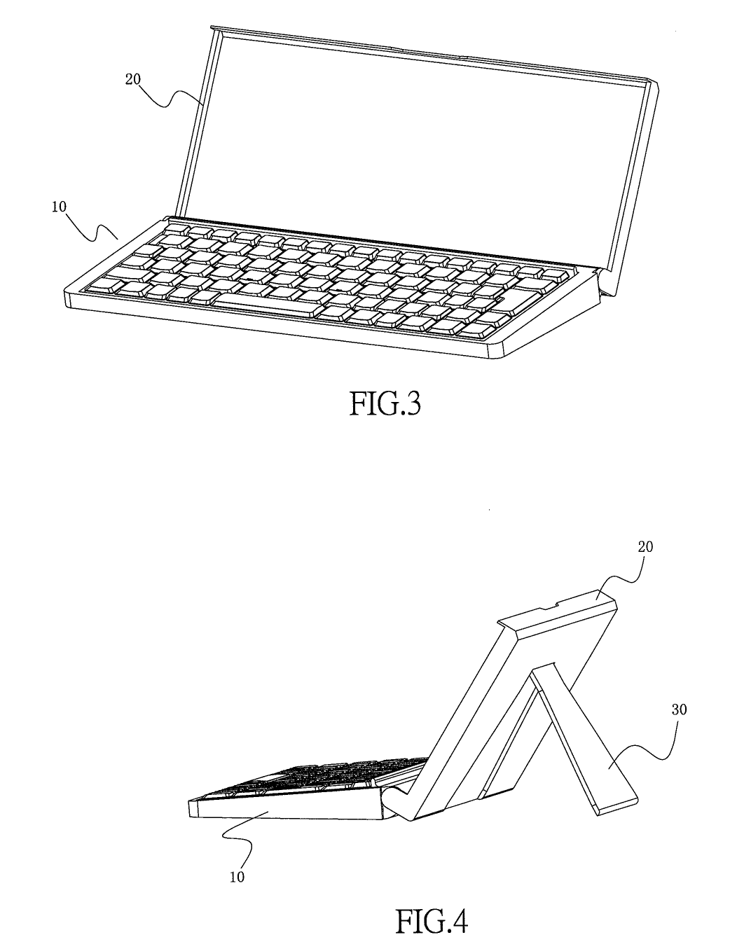

Referring to FIG. 3, it shows a three-dimensional front view of the present invention, with that the rotational keyboard cover 20 and the rotational bracket (not shown in the drawing) are turned open.

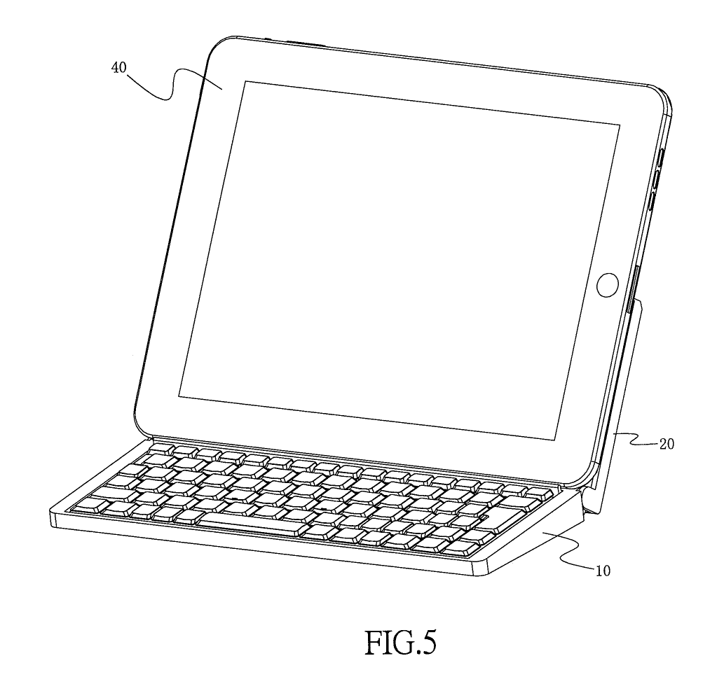

Referring to FIG. 4, it shows a three-dimensional rear view of the present invention, with that the rotational keyboard cover 20 and the rotational bracket 30 are turned open.

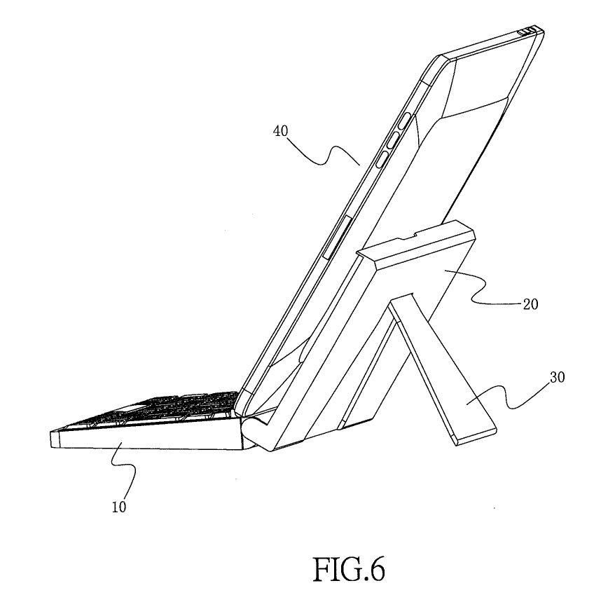

Referring to FIG. 5, it shows a three-dimensional front view of the present invention, wherein a tablet personal computer 40 is emplaced after the rotational keyboard cover 20 and the bracket (not shown in the drawing) have been turned open.

Referring to FIG. 6, it shows a three-dimensional rear view of the present invention, wherein the tablet personal computer 40 is emplaced after the rotational keyboard cover 20 and the bracket 30 have been turned open.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A slim keyboard with a function of a tablet personal computer bracket, comprising:
a keyboard unit;
a rotational keyboard cover which is used to cover the keyboard unit and to install a rotational bracket; wherein
the rotational bracket which is used to support the keyboard cover.

2. The slim keyboard with a function of a tablet personal computer bracket, according to claim 1, wherein the keyboard unit is provided with a bump thereby limiting the position of a tablet personal computer.

3. The slim keyboard with a function of a tablet personal computer bracket, according to claim 1, wherein the rotational bracket is provided on the rotational keyboard cover.
